(19) United States
(12) Patent Application Publication
(10) Pub. No.: US 2026/0196645 A1
(43) Pub. Date: Jul. 9, 2026

(54) EXPLOSION-PROOF VENTING VALVE DEVICE

(71) Applicant: MANN+HUMMEL GmbH, Ludwigsburg (DE)

(72) Inventors: Lan WEI, Shanghai (CN); Yang LI, Shanghai (CN); Shuaipeng HUO, Shanghai (CN); Shenjian LI, Shanghai (CN)

(21) Appl. No.: 19/440,811

(22) Filed: Jan. 6, 2026

Related U.S. Application Data
(63) Continuation of application No. PCT/CN2025/071142, filed on Jan. 8, 2025.

(51) Int. Cl. H01M 50/333; B01D 46/00; B01D 46/12; B01D 46/62; B01D 53/04; F16K 17/04; H01M 50/30

(52) U.S. Cl. CPC H01M 50/333; B01D 46/0004; B01D 46/0036; B01D 46/12; B01D 46/62; B01D 53/0407; F16K 17/0413; H01M 50/394; B01D 2271/02; B01D 2279/35; B01D 2279/45; H01M 2200/20

(57) ABSTRACT

An explosion-proof venting valve for a battery pack includes a top cover having a cover hole, a valve body removably mounted to the top cover, the valve body including a first mounting portion and a second mounting portion, a membrane being water-impermeable and gas-permeable, the membrane interposed between the valve body and the top cover, an intake valve assembly mounted into the first mounting portion in a first mounting direction, a venting valve assembly mounted into the second mounting portion in a second mounting direction opposite to the first mounting direction, and a filter assembly removably mounted to the valve body. A battery pack including a battery pack housing and the explosion-proof venting valve mounted to the battery housing is also provided.

### CROSS-REFERENCE TO RELATED APPLICATION

This application is a continuation application of international application No. PCT/CN2025/071142 having an international filing date of Jan. 8, 2025, and designating the United States, the entire contents of the aforesaid application being incorporated herein by reference.

### TECHNICAL FIELD

Embodiments of the invention relate to an explosion-proof venting valve device, and more specifically to an explosion-proof venting valve device for a battery pack used for example in an electric vehicle.

### BACKGROUND

Currently, due to the change of altitude and ambient temperature during driving electric vehicles, there is a significant pressure difference between interior and exterior of the battery pack. If the pressure difference between interior and exterior of the battery pack is not balanced in time, the battery pack will have a risk of compression deformation and expansion or even bursting under the action of the pressure difference. In some cases, a large amount of gases will be released in the case of thermal runaway of the battery cell inside the battery pack, and if these gases are not discharged to the exterior of the battery pack in time, internal pressure of the battery pack will rise sharply in a short period of time, resulting in bursting or even explosion of the battery pack, which will affect safety of passengers.

Therefore, it is necessary to install an explosion-proof vent valve at an outer end of the battery pack to equalize the pressure, while reducing the effect of water condensation on the battery pack and providing explosion-proof function in emergency conditions. The existing explosion-proof venting valve mostly adopts a single area with integral ventilation and explosion-proof function, however, contaminants such as mud, dust, water accumulation and the like that top cover the membrane is easy to block the membrane, and thus may lose the function of breathability.

Batteries release a lot of heat during heat runaway events. There is a chemical reaction between the positive and negative electrodes inside the battery, and when the battery is short-circuited or overcharged, this reaction becomes very violent, causing the temperature inside the battery to rise sharply. Once the heat limit of the battery is exceeded, the battery burns and releases a large amount of heat. At the same time, the electrolyte in the battery usually contains substances such as organic solvents and fluoride, which will decompose to produce toxic gases, such as fluoride, cyanide, carbon monoxide, etc. These toxic gases are harmful to human health and may lead to poisoning or even inhalation if being inhaled by humans too much. Materials inside the battery include potassium salts, lithium manganese oxide, etc., which produce a lot of smoke when burned. Smoke contains large amounts of fine particulate matter and organic matter, which pollutes air quality and increases the risk of fire spreading. The housing of the battery pack is usually made of metal materials such as aluminum, cobalt, manganese, etc., and when the battery bursts, the housing may crack, releasing metal fragments. These metal fragments may not only cause human injury but may also cause secondary fires. The existing explosion-proof valves cannot adsorb harmful gases and filter other harmful substances when the battery is abnormally vented in an emergency and cannot achieve that the flue gas is invisible.

To this end, it is desirable to develop an explosion-proof venting valve that is simple in structure, integrates filtering function, and reliably works under different operating conditions.

### SUMMARY

An object of the present disclosure is to provide an explosion-proof venting valve that is simple in structure, integrates filtering function, and reliably works under different operating conditions.

In one aspect, an explosion-proof venting valve is provided. The explosion-proof venting valve includes a top cover having a cover hole, a valve body removably mounted to the top cover, the valve body including a first mounting portion and a second mounting portion, and a membrane being water-impermeable and gas-permeable, the membrane being interposed between the valve body and the top cover. The explosion-proof venting valve further includes an intake valve assembly mounted into the first mounting portion in a first mounting direction, a venting valve assembly mounted into the second mounting portion in a second mounting direction opposite to the first mounting direction, and a filter assembly removably mounted to the valve body, the filter assembly including a filter housing defining a filter space, a filter cover removably mounted to the filter housing, a first filter element disposed in the filter space, a second filter element disposed on the first filter element in the filter space, and a third filter element disposed on the second filter element in the filter space.

The first filter element may include first meshes with a first mesh size, the second filter element may include second meshes with a second mesh size less than the first mesh size, and the third filter element may include third meshes with a third mesh size less than the second mesh size, and may include absorbent for absorbing harmful gas.

The membrane may include a hydrophobic coating thereon.

The top cover may include a plurality of elastic tabs extending downwardly from the top cover, each of the plurality of elastic tabs including a through-hole, the valve body may include a corresponding plurality of protrusions corresponding to the plurality of elastic tabs, and the plurality of elastic tabs may be respectively slidable over the plurality of protrusions on the valve body and then each of the plurality of protrusions snaps into the through-hole of a respective one of the plurality of elastic tabs and holds the top cover and the valve body in place.

The venting valve assembly may be larger than the intake valve assembly.

The intake valve assembly may include a first upper member, a first lower member, and a first compression spring interposed between the first upper member and the first lower member.

The first upper member may include a first valve plate, a first circumferential groove for receiving a first valve seal, a plurality of first upper guide portions extending radially outwardly from the first upper member, and a first upper cylindrical portion extending downwardly from the first valve plate. The first lower member may include a first support plate with at least one intake hole, a first lower cylindrical portion extending upwardly from the first support plate, and a plurality of first lower guide portions extending upwardly around an outer perimeter of the first support plate, the first lower cylindrical portion defining a first central hole extending axially for receiving the first upper cylindrical portion, and the plurality of first upper guide portions and the plurality of first lower guide portions being circumferentially staggered with each other. The first mounting portion may include a first valve seat with a first valve aperture, and multiple pairs of first axial guide fins extending radially inwardly from an inner wall of the first mounting portion, the first compression spring being for biasing the first valve plate to rest against the first valve seat in a fluid tight manner, each of the plurality of first upper guide portions being slidable axially along a first upper guide gap between a respective pair of the first axial guide fins, and each of the plurality of first lower guide portions being slidable axially along a first lower guide gap between an adjacent pair of the first axial guide fins.

The first lower member may further include a first circumferential elastic lip extending radially outwardly around the outer perimeter of the first support plate, the first mounting portion including a first circumferential protrusion extending radially inwardly from a bottom of the inner wall of the first mounting portion.

The venting valve assembly may include a second upper member, a second lower member, and a second compression spring interposed between the second upper member and the second lower member.

The second lower member may include a second valve plate, a second circumferential groove for receiving a second valve seal, a plurality of second lower guide portions extending radially outwardly from the second lower member, and a second lower cylindrical portion extending upwardly from the second valve plate. The second upper member may include a second support plate with at least one venting hole, a second upper cylindrical portion extending downwardly from the second support plate, and a plurality of second upper guide portions extending downwardly around an outer perimeter of the second support plate, the second upper cylindrical portion defining a second central hole extending axially for receiving the second lower cylindrical portion, and the plurality of second upper guide portions and the plurality of second lower guide portions being circumferentially staggered with each other. The second mounting portion may include a second valve seat with a second valve aperture, and multiple pairs of second axial guide fins extending radially inwardly from an inner wall of the second mounting portion, the second compression spring being for biasing the second valve plate to rest against the second valve seat in a fluid tight manner, each of the plurality of second lower guide portions being slidable axially along a second lower guide gap between a respective pair of the second axial guide fins, and each of the plurality of second upper guide portions being slidable axially along a second upper guide gap between an adjacent pair of the second axial guide fins.

The second upper member may further include a second circumferential elastic lip extending radially outwardly around the outer perimeter of the second support plate, the second mounting portion including a second circumferential protrusion extending radially inwardly from a top of the inner wall of the second mounting portion.

The filter cover may include a grid cover body including a plurality of filter cover apertures, and a circumferential filter groove including circumferential outer surface of the cover body and for receiving a filter seal.

The valve body may include a circumferential body groove disposed in a bottom surface of the valve body and for receiving a body seal, the circumferential body groove being further disposed at a distance outwardly from the filter assembly.

The body seal may include an annular body, an inner circumferential lip extending radially inwardly from the annular body, and an outer circumferential lip extending radially outwardly from the annular body.

In another aspect, a battery pack is provided. The battery pack includes a battery housing, at least one battery cell disposed in the battery housing, and the explosion-proof venting valve device as described above and mounted to the battery housing.

By means of the filter assembly, toxic gases, particulate matter and/or metal fragments may be reliably filtered out when a thermal runaway event takes place in the battery pack.

The filter assembly is preassembled as a module, and may be easily mounted to the valve body, thus facilitating assembly and replacement of the filter assembly.

By means of the multi-stage filtration of the filter assembly, particles of different sizes, liquid and/or harmful gas are reliably filtered out or absorbed, and the larger particles may be intercepted in the first filter element of the filter assembly to prevent from blocking the second or third filter element, resulting in unobstructed exhaust gas flow during thermal runaway event, and then avoiding explosion of the battery pack.

By means of the filter assembly, the mesh size of the first filter element, the second filter element, and the third filter element may be flexibly adjusted according to the different volume of exhaust gas caused by the type of different battery packs, the quantity, nature, and size of the particles contained in the exhaust gas.

The spring constant of the first compression spring and/or the second compression spring may be adjusted for different application scenarios and internal pressure emergency relief demands, thus exhibiting excellent scalability.

By means of the hydrophobic coating, moisture in ambient air may be prevented from entering the filter assembly, thus increasing service life of the filter assembly.

The venting valve assembly used as a venting valve is larger than the intake valve assembly used as an intake valve, thus saving the total cost of the explosion-proof venting valve, while at the same time ensuring proper operation of the explosion-proof venting valve.

By means of the first axial guide fins shared by the first lower guide portion and the first upper guide portion, the intake valve assembly may be reliably positioned and guided in the valve body with a simple structure, and saves cost as compared with separate guide fins for the first lower guide portion and the first upper guide portion.

By means of the second axial guide fins shared by the second lower guide portion and the second upper guide portion, the venting valve assembly may be reliably positioned and guided in the valve body with a simple structure, and saves cost as compared with separate guide fins for the second lower guide portion and the second upper guide portion.

Further areas of applicability of the present disclosure will become apparent from the detailed description and the accompanying drawings. The detailed description and exemplary embodiments are intended for purposes of illustration only and are not intended to limit the scope of the disclosure.

### BRIEF DESCRIPTION OF DRAWINGS

The present disclosure will become more fully understood from the following detailed description and the accompanying drawings.

FIG. 1 is a schematic exploded view of an example explosion-proof venting valve according to embodiments of the invention, wherein the intake valve assembly and the venting valve assembly are omitted for clarity.

FIG. 2 is a schematic cross-sectional view of the explosion-proof venting valve of FIG. 1, wherein the explosion-proof venting valve is in neither an intake mode nor a venting mode, the intake valve assembly is in a closed state, and the venting valve assembly is in a closed state.

FIG. 3 is a schematic exploded view of an example intake valve assembly according to embodiments of the invention.

FIG. 4 is a schematic exploded view of an example venting valve assembly according to embodiments of the invention.

FIG. 5 is a schematic perspective view of an example valve body according to embodiments of the invention.

FIG. 6 is a schematic top view of the valve body of FIG. 5.

FIG. 7 is a schematic cross-sectional view of the explosion-proof venting valve of FIG. 1, wherein the explosion-proof venting valve is in a venting mode, the intake valve assembly is in a closed state, and the venting valve assembly is in an open state.

FIG. 8 is a schematic cross-sectional view of the explosion-proof venting valve of FIG. 1, wherein the explosion-proof venting valve is in an intake mode, the intake valve assembly is in an open state, and the venting valve assembly is in a closed state.

### DETAILED DESCRIPTION

The following detailed description is merely exemplary in nature and is not intended to limit the present disclosure, application, or uses. It should be understood that throughout the drawings, corresponding reference numerals indicate the same, like or corresponding parts and features. Additionally, the drawings are generally schematic and not necessarily to scale. Some features may be exaggerated or minimized to show details of particular components. Therefore, specific structural and functional details disclosed herein are not to be interpreted as limiting, but merely as a representative basis for teaching one skilled in the art to variously make, use and employ the present disclosure.

Certain terminology may be used in the following detailed description for the purpose of reference only and thus are not intended to be limiting. For example, terms such as “above” and “below” refer to directions in the drawings to which reference is made. Terms such as “front”, “back”, “fore”, “aft”, “left”, “right”, “rear”, “side”, “upward”, “downward”, “horizontal”, “vertical”, “top”, and “bottom”, etc., describe the orientation and/or location of portions of the components or elements within a consistent but arbitrary frame of reference, which is made clear by reference to the text and the associated drawings describing the components or elements under discussion.

Furthermore, terms such as “first”, “second”, “third”, and so on may be used to describe separate components. Such terminologies are used descriptively for the drawing figures, and do not represent limitations on the scope of the disclosure, as defined by the appended claims.

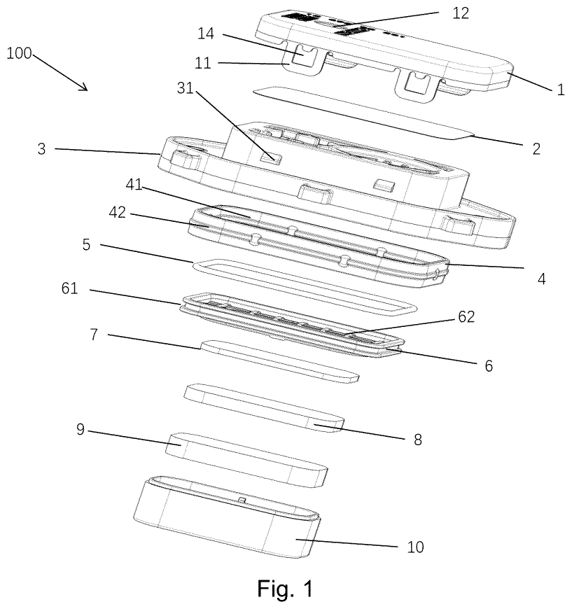

Referring now to the drawings, wherein like reference numbers refer to like features throughout the several views. FIG. 1 is a schematic exploded view of an example explosion-proof venting valve 100 according to embodiments of the invention. The explosion-proof venting valve 100 is used for a battery pack suitable for example for use in an electric vehicle. However, as shall be understood for those skilled in the art, the explosion-proof venting valve 100 may be used in any other suitable application as needed, without departing the scope of the disclosure.

According to one example illustrated by FIGS. 1-8, the explosion-proof venting valve 100 may comprise a top cover 1; a valve body 3 engaged with the top cover 1; a membrane 2; an intake valve assembly 110; a venting valve assembly 120; and a filter assembly.

The membrane 2 is water-impermeable and is gas-permeable. The membrane 2 is disposed on top of the valve body 3 and under the top cover 1. According to one example, the membrane 2 may be disposed on the top surface 34 of the valve body 3, as shall be understood for those skilled in the art, the membrane 2 may be disposed on any other suitable position, without departing the scope of the disclosure. The membrane 2 may be fixed to the valve body 3 by any suitable means, such as by adhesive. The membrane 2 may be formed of a microporous material. The micropores in the material enable a gas transport through the membrane 2 but prevent moisture transport through the membrane 2. For example, the membrane 2 may be formed of for example perfluorosulfonic acid, however, as shall be understood for those skilled in the art, the membrane 2 may be formed of any other suitable materials as needed, without departing the scope of the disclosure. The membrane 2 may be provided with a hydrophobic coating thereon. By means of the hydrophobic coating, moisture in ambient air may be prevented from entering the filter assembly, thus increasing service life of the filter assembly.

The top cover 1 may include a top wall, and a cover hole 12 extending through the top wall. According to one example, the top cover 1 may be provided with one cover hole 12, however, as shall be understood for those skilled in the art, the top cover 1 may be provided with any suitable number of cover hole 12 as needed, such as 2, 3, 4, etc., without departing the scope of the disclosure. In addition, a plurality of cover holes 12 may be arrayed in any suitable pattern.

The valve body 3 is removably mounted to the top cover 1. According to one example, the top cover 1 may be provided with a plurality of elastic tabs 11 extending downwardly from the top cover 1, and the valve body 3 may be provided with a corresponding plurality of protrusions 31. Each elastic tab 11 may comprise a through-hole 14. The elastic tab 11 may slide over a corresponding protrusion 31 on the valve body 3 and then the protrusion 31 snaps into the through-hole 14 and holds the top cover 1 and the valve body 3 in place. As shall be understood for those skilled in the art, the valve body 3 may be removably mounted to the top cover 1 by any other suitable means, without departing the scope of the disclosure.

The valve body 3 is provided with a plurality of fastening holes 32. According to one example, the valve body 3 is provided with two fastening holes 32 at opposite ends thereof. However, as shall be understood for those skilled in the art, the valve body 3 may be provided with any other suitable number of fastening holes 32, without departing the scope of the disclosure.

The filter assembly is removably mounted below the valve body 3. The filter assembly comprises: a filter housing 10 defining a filter space, a filter cover 6 removably mounted to the filter housing 10, a first filter element 9 disposed in the filter space, a second filter element 8 disposed above the first filter element 9 in the filter space, and a third filter element 7 disposed above the second filter element 8 in the filter space.

The filter cover 6 may comprise a grid cover body with a plurality of filter cover apertures 62, and a circumferential filter groove 61 provided in the circumferential outer surface of the cover body and configured to receive a filter seal 5. The filter housing 10 may also comprise a grid bottom plate with a plurality of filter housing apertures 102, so that gas may pass through the filter assembly.

The first filter element 9 may comprise first meshes with a first mesh size, the second filter element 8 may comprise second meshes with a second mesh size, the third filter element 7 may comprise third meshes with a third mesh size, the second mesh size is less than the first mesh size, the third mesh size is less than the second mesh size, and the third filter element 7 may comprise absorbent for absorbing harmful gas. As understood by those skilled in the art, the filter assembly may comprise any other suitable number of filter elements as needed, such as 2, 4, etc., without departing the scope of the disclosure. In addition, relative position of the first filter element 9, the second filter element 8 and the third filter element 7, for example, the position of the first filter element 9 and the second filter element 8 may be interchanged, or the filter element 7 may be disposed under the first filter element 9 and the second filter element 8.

By means of the filter assembly, toxic gases, particulate matter and/or metal fragments are reliably filtered out when a thermal runaway event takes place in the battery pack.

The filter assembly is preassembled as a module and may be easily mounted to the valve body 3, thus facilitating assembly and replacement of the filter assembly.

By means of the multi-stage filtration of the filter assembly, particles of different sizes, liquid and/or harmful gas may be reliably filtered out or absorbed, and the larger particles may be intercepted in the first filter element 9 of the filter assembly to prevent from blocking the second or third filter element, resulting in unobstructed exhaust gas flow during thermal runaway event, and then avoiding explosion of the battery pack.

By means of the filter assembly, the mesh size of the first filter element 9, the second filter element 8, and the third filter element 7 may be flexibly adjusted according to the different volume of exhaust gas caused by the type of different battery packs, the quantity, nature, and size of the particles contained in the exhaust gas.

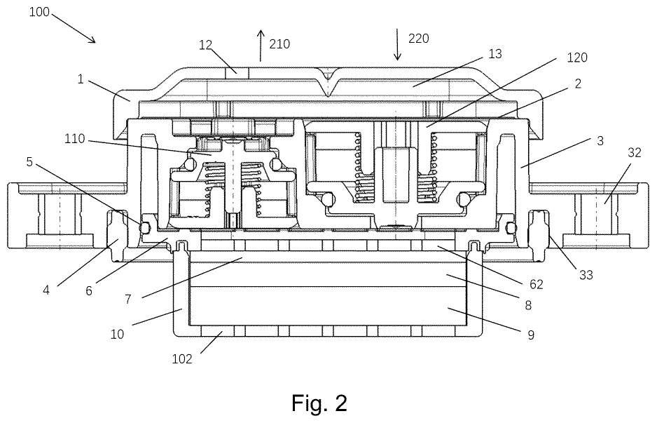

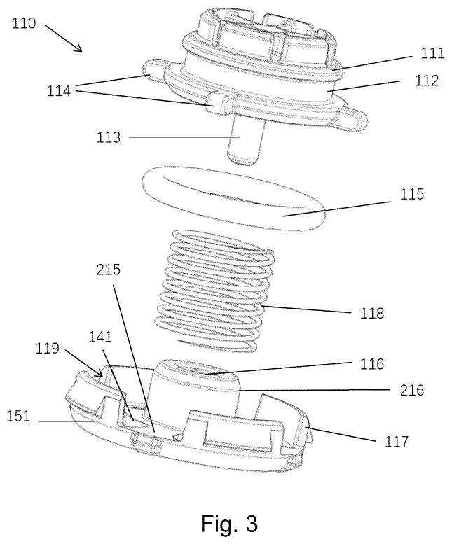

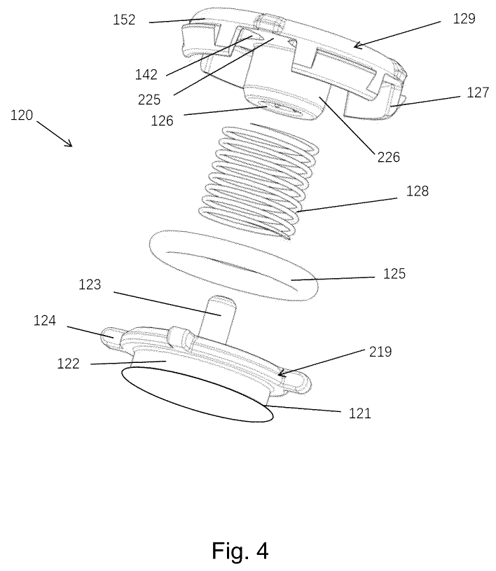

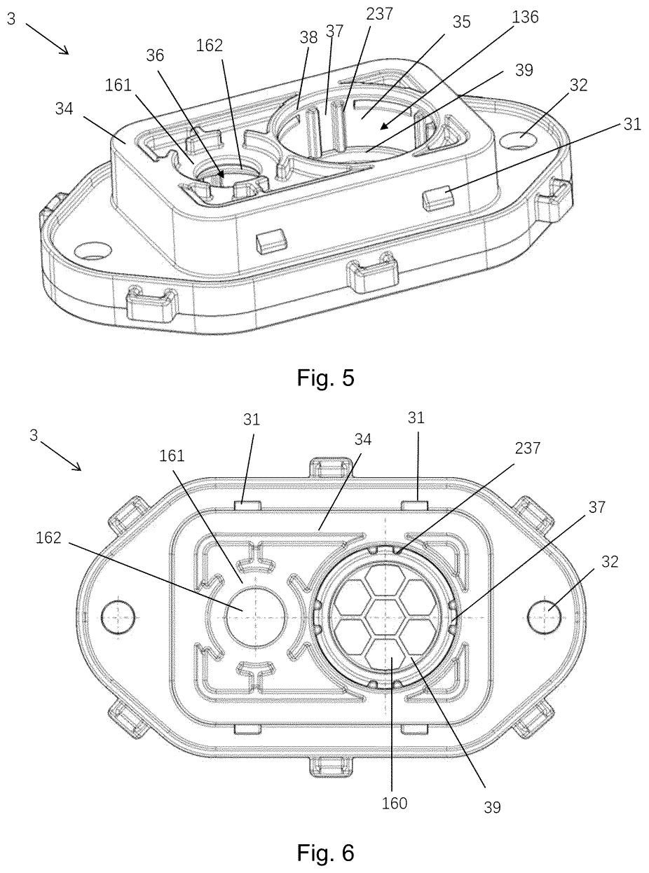

FIG. 2 is a schematic cross-sectional view of the explosion-proof venting valve 100 of FIG. 1, wherein the explosion-proof venting valve 100 is in neither an intake mode nor a venting mode, the intake valve assembly 110 is in a closed state, and the venting valve assembly 120 is in a closed state. FIG. 3 is a schematic exploded view of an example intake valve assembly 110 according to embodiments. FIG. 4 is a schematic exploded view of an example venting valve assembly 120 according to embodiments. FIG. 5 is a schematic perspective view of an example valve body 3 according to embodiments. FIG. 6 is a schematic top view of the valve body 3 of FIG. 5.

The valve body 3 is provided with a first mounting portion 36 and a second mounting portion 136. The intake valve assembly 110 is mounted into the first mounting portion 36 in a first mounting direction 210, and the venting valve assembly 120 is mounted into the second mounting portion 136 in a second mounting direction 220 opposite to the first mounting direction 210.

The venting valve assembly 120 may be used as a venting valve, and the intake valve assembly 110 may be used as an intake valve, and the venting valve assembly 120 may be larger than the intake valve assembly 110, thus saving the total cost of the explosion-proof venting valve 100, while at the same time ensuring proper operation of the explosion-proof venting valve 100.

The valve body 3 may be provided with a circumferential body groove 33 located in the bottom surface of the valve body 3 and configured to receive a body seal 4, wherein the circumferential body groove 33 is positioned at a distance outwardly from the filter assembly.

The body seal 4 may comprise an annular body, an inner circumferential lip 41 extending radially inwardly from the annular body, and an outer circumferential lip 42 extending radially outwardly from the annular body. As shall be understood for those skilled in the art, the body seal 4 may be any other suitable structure, without departing the scope of the disclosure.

According to one example, the intake valve assembly 110 may comprise a first upper member 111, a first lower member 119, and a first compression spring 118 disposed between the first upper member 111 and the first lower member 119, as shown in FIG. 3. As shall be understood for those skilled in the art, the intake valve assembly 110 may be any other suitable structure, without departing the scope of the disclosure.

The spring constant of the first compression spring 118 may be adjusted for different application scenarios and internal pressure emergency relief demands, thus exhibiting excellent scalability.

The first upper member 111 may comprise a first valve plate, a first circumferential groove 112 for receiving a first valve seal 115, a plurality of first upper guide portions 114 extending radially outwardly from the first upper member 111, and a first upper cylindrical portion 113 extending downwardly from the first valve plate.

The first lower member 119 may comprise a first support plate 215 with at least one intake hole 141, a first lower cylindrical portion 216 extending upwardly from the first support plate 215, and a plurality of first lower guide portions 117 extending upwardly around the outer perimeter of the first support plate 215, the first lower cylindrical portion 216 defining a first central hole 116 extending axially for receiving the first upper cylindrical portion 113. The plurality of first upper guide portion 114 and the plurality of first lower guide portion 117 are circumferentially staggered with each other.

The first mounting portion 36 comprises a first valve seat 161 with a first valve aperture 162, and multiple pairs of first axial guide fins (not shown) extending radially inwardly from the inner wall of the first mounting portion 36, the first compression spring 118 being configured to bias the first valve plate to seat against the first valve seat 161 in fluid tight manner, each first upper guide portion 114 may slide axially along first upper guide gaps between a respective pair of first axial guide fins, and each first lower guide portion 117 may slide axially along first lower guide gaps between adjacent pairs of first axial guide fins.

By means of the first axial guide fins shared by the first lower guide portion 117 and the first upper guide portion 114, the intake valve assembly 110 may be reliably positioned and guided in the valve body 3 with a simple structure, and saves the cost as compared with separate guide fins for the first lower guide portion 117 and the first upper guide portion 114.

The first lower member 119 may further comprise a first circumferential elastic lip 151 extending radially outwardly around the outer perimeter of the first support plate 215, the first mounting portion 36 comprises a first circumferential protrusion extending radially inwardly from the bottom of the inner wall of the first mounting portion 36. In this regard, the intake valve assembly 110 may be reliably mounted to the first mounting portion 36. As shall be understood for those skilled in the art, the intake valve assembly 110 may be mounted to the first mounting portion 36 by any other suitable means, without departing the scope of the disclosure.

The venting valve assembly 120 may have similar structure to that of the intake valve assembly 110, for example, the venting valve assembly 120 may comprise a second upper member 129, a second lower member 219, and a second compression spring 128 disposed between the second upper member 129 and the second lower member 219, as shown in FIG. 4. As shall be understood for those skilled in the art, the venting valve assembly 120 may be any other suitable structure, without departing the scope of the disclosure.

The spring constant of the second compression spring 128 may be adjusted for different application scenarios and internal pressure emergency relief demands, thus exhibiting excellent scalability.

The second lower member 219 may comprise a second valve plate 121, a second circumferential groove 122 for receiving a second valve seal 125, a plurality of second lower guide portions 124 extending radially outwardly from the second lower member 219, and a second lower cylindrical portion 123 extending upwardly from the second valve plate 121.

The second upper member 129 may comprise a second support plate 225 with at least one venting hole 142, a second upper cylindrical portion 226 extending downwardly from the second support plate 225, and a plurality of second upper guide portions 127 extending downwardly around outer perimeter of the second support plate 225, the second upper cylindrical portion 226 defining a second central hole 126 extending axially for receiving the second lower cylindrical portion 123, the plurality of second upper guide portions 127 and the plurality of second lower guide portions 124 are circumferentially staggered with each other.

The second mounting portion 136 may comprise a second valve seat 39 with a second valve aperture 160, and multiple pairs of second axial guide fins 237 extending radially inwardly from the inner wall of the second mounting portion 136, the second compression spring 128 being configured to bias the second valve plate 121 to seat against the second valve seat 39 in fluid tight manner, each second lower guide portion 124 may slide axially along second lower guide gaps 37 between a respective pair of second axial guide fins 237, and each second upper guide portion 127 may slide axially along second upper guide gaps 35 between adjacent pairs of second axial guide fins 237.

By means of the second axial guide fins 237 shared by the second lower guide portion 124 and the second upper guide portion 127, the venting valve assembly 120 may be reliably positioned and guided in the valve body 3 with a simple structure, and saves the cost as compared with separate guide fins for the second lower guide portion 124 and the second upper guide portion 127.

The second upper member 129 may further comprise a second circumferential elastic lip 152 extending radially outwardly around the outer perimeter of the second support plate 225, the second mounting portion 136 comprises a second circumferential protrusion 38 extending radially inwardly from the top of the inner wall of the second mounting portion 136. In this regard, the venting valve assembly 120 may be reliably mounted to the second mounting portion 136. As shall be understood for those skilled in the art, the venting valve assembly 120 may be mounted to the second mounting portion 136 by any other suitable means, without departing the scope of the disclosure.

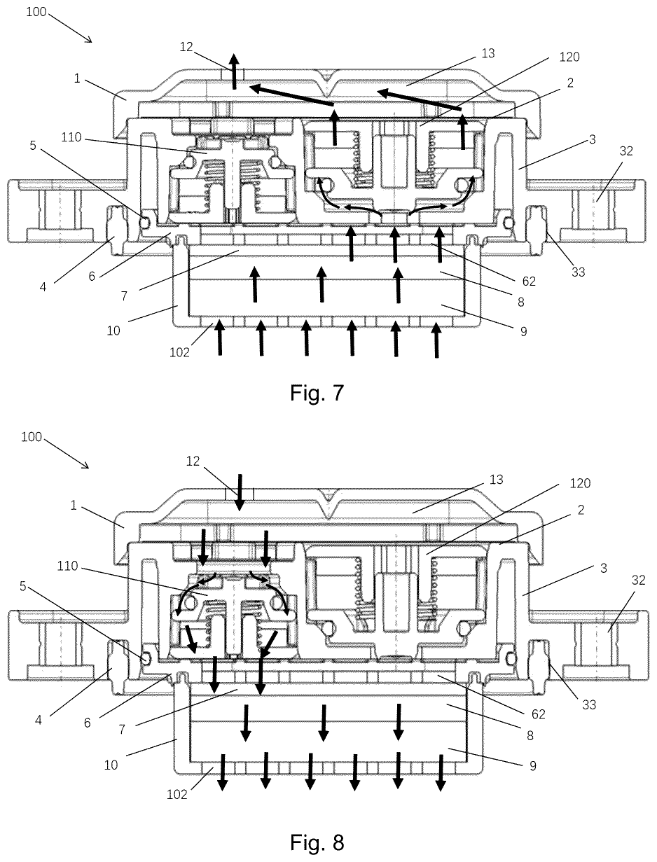

FIG. 7 is a schematic cross-sectional view of the explosion-proof venting valve 100 of FIG. 1, wherein the explosion-proof venting valve 100 is in a venting mode, the intake valve assembly 110 is in a closed state, and the venting valve assembly 120 is in an open state.

When a pressure of the interior of the battery pack is greater than environment pressure by a first threshold, the pressure difference will overcome a force of the second compression spring 128, thereby urging the second valve plate 121 away from the second valve seat 39, and thus the explosion-proof venting valve 100 is in the venting mode. The first threshold is dependent on the spring constant of the second compression spring 128. In the venting mode, gas inside of the battery pack flows out to the environment as arrows, specifically, the gas flows through the filter housing apertures 102, the first filter element 9, the second filter element 8, the third filter element 7, the filter cover apertures 62, the at least one venting hole 142 of the venting valve assembly 120, space 13 between the top cover 1 and the membrane 2, and thus flows out to the environment via the cover hole 12.

FIG. 8 is a schematic cross-sectional view of the explosion-proof venting valve 100 of FIG. 1, wherein the explosion-proof venting valve 100 is in an intake mode, the intake valve assembly 110 is in an open state, and the venting valve assembly 120 is in a closed state.

When a pressure of the interior of the battery pack is less than environment pressure by a second threshold, the pressure difference will overcome force of the first compression spring 118, thereby urging the first valve plate away from the first valve seat 161, and thus the explosion-proof venting valve 100 is in the intake mode. The second threshold is dependent on the spring constant of the first compression spring 118. In the intake mode, ambient air flows into the battery pack as indicated by the arrows, specifically, the ambient air flows through the cover hole 12, space 13 between the top cover 1 and the membrane 2, the intake hole 141 of the intake valve assembly 110, the filter cover apertures 62, the third filter element 7, the second filter element 8, the first filter element 9, the filter cover apertures 102, and thus flows into the battery pack.

In another aspect, a battery pack is provided. The battery pack comprises: a battery housing; at least one battery cell disposed in the battery housing; and the explosion-proof venting valve device 100 mounted to the battery housing.

Aspects of the present disclosure have been described in detail with reference to the illustrated embodiments; those skilled in the art will recognize, however, that many modifications may be made thereto without departing from the scope of the present disclosure. The present disclosure is not limited to the precise construction and compositions disclosed herein; any and all modifications, changes, and variations apparent from the foregoing descriptions are within the scope of the disclosure as defined by the appended claims. Moreover, the present concepts expressly include any and all combinations and sub-combinations of the preceding elements and features.

That which is claimed is:

1. An explosion-proof venting valve comprising:
a top cover comprising a cover hole;
a valve body removably mounted to the top cover, the valve body comprising a first mounting portion and a second mounting portion;
a membrane being water-impermeable and gas-permeable, the membrane being interposed between the valve body and the top cover;
an intake valve assembly mounted into the first mounting portion in a first mounting direction;
a venting valve assembly mounted into the second mounting portion in a second mounting direction opposite to the first mounting direction; and
a filter assembly removably mounted to the valve body, the filter assembly comprising:
a filter housing defining a filter space;
a filter cover removably mounted to the filter housing;
a first filter element disposed in the filter space;
a second filter element disposed on the first filter element in the filter space; and
a third filter element disposed on the second filter element in the filter space.

2. The explosion-proof venting valve according to claim 1, wherein the first filter element comprises first meshes with a first mesh size,
the second filter element comprises second meshes with a second mesh size less than the first mesh size, and
the third filter element comprises third meshes with a third mesh size less than the second mesh size and comprises absorbent for absorbing harmful gas.

3. The explosion-proof venting valve according to claim 1, wherein the membrane comprises a hydrophobic coating thereon.

4. The explosion-proof venting valve according to claim 1, wherein the top cover comprises a plurality of elastic tabs extending downwardly from the top cover, each of the plurality of elastic tabs comprising a through-hole,
the valve body comprises a plurality of protrusions corresponding to the plurality of elastic tabs, and
the plurality of elastic tabs are respectively slidable over the plurality of protrusions on the valve body and then each of the plurality of protrusions snaps into the through-hole of a respective one of the plurality of elastic tabs and holds the top cover on the valve body.

5. The explosion-proof venting valve according to claim 1, wherein the venting valve assembly is larger than the intake valve assembly.

6. The explosion-proof venting valve according to claim 5, wherein the intake valve assembly comprises:
a first upper member;
a first lower member; and
a first compression spring interposed between the first upper member and the first lower member.

7. The explosion-proof venting valve according to claim 6, wherein the first upper member comprises a first valve plate, a first circumferential groove for receiving a first valve seal, a plurality of first upper guide portions extending radially outwardly from the first upper member, and a first upper cylindrical portion extending downwardly from the first valve plate,
the first lower member comprises a first support plate with at least one intake hole, a first lower cylindrical portion extending upwardly from the first support plate, and a plurality of first lower guide portions extending upwardly around an outer perimeter of the first support plate, the first lower cylindrical portion defining a first central hole extending axially for receiving the first upper cylindrical portion, and the plurality of first upper guide portions and the plurality of first lower guide portions being circumferentially staggered with each other, and
the first mounting portion comprises a first valve seat with a first valve aperture, and multiple pairs of first axial guide fins extending radially inwardly from an inner wall of the first mounting portion, the first compression spring configured for biasing the first valve plate to rest against the first valve seat in a fluid tight manner, each of the plurality of first upper guide portions being slidable axially along a first upper guide gap between a respective pair of the first axial guide fins, and each of the plurality of first lower guide portions being slidable axially along a first lower guide gap between an adjacent pair of the first axial guide fins.

8. The explosion-proof venting valve according to claim 7, wherein the first lower member further comprises a first circumferential elastic lip extending radially outwardly around the outer perimeter of the first support plate, the first mounting portion comprising a first circumferential protrusion extending radially inwardly from a bottom of the inner wall of the first mounting portion.

9. The explosion-proof venting valve according to claim 5, wherein the venting valve assembly comprises:
a second upper member;
a second lower member; and
a second compression spring interposed between the second upper member and the second lower member.

10. The explosion-proof venting valve according to claim 9, wherein the second lower member comprises a second valve plate, a second circumferential groove for receiving a second valve seal, a plurality of second lower guide portions extending radially outwardly from the second lower member, and a second lower cylindrical portion extending upwardly from the second valve plate,
the second upper member comprises a second support plate with at least one venting hole, a second upper cylindrical portion extending downwardly from the second support plate, and a plurality of second upper guide portions extending downwardly around an outer perimeter of the second support plate, the second upper cylindrical portion defining a second central hole extending axially for receiving the second lower cylindrical portion, and the plurality of second upper guide portions and the plurality of second lower guide portions being circumferentially staggered with each other, and
the second mounting portion comprises a second valve seat with a second valve aperture, and multiple pairs of second axial guide fins extending radially inwardly from an inner wall of the second mounting portion, the second compression spring being for biasing the second valve plate to rest against the second valve seat in a fluid tight manner, each of the plurality of second lower guide portions being slidable axially along a second lower guide gap between a respective pair of the second axial guide fins, and each of the plurality of second upper guide portions being slidable axially along a second upper guide gap between an adjacent pair of the second axial guide fins.

11. The explosion-proof venting valve according to claim 10, wherein the second upper member further comprises a second circumferential elastic lip extending radially outwardly around the outer perimeter of the second support plate, the second mounting portion comprising a second circumferential protrusion extending radially inwardly from a top of the inner wall of the second mounting portion.

12. The explosion-proof venting valve according to claim 1, wherein the filter cover comprises:
a grid cover body comprising a plurality of filter cover apertures; and
a circumferential filter groove comprising a circumferential outer surface of the grid cover body and configured for receiving a filter seal.

13. The explosion-proof venting valve according to claim 1, wherein the valve body comprises a circumferential body groove disposed in a bottom surface of the valve body and configured for receiving a body seal, the circumferential body groove being further disposed at a distance outwardly from the filter assembly.

14. The explosion-proof venting valve according to claim 13, wherein the body seal comprises:
an annular body;
an inner circumferential lip extending radially inwardly from the annular body; and
an outer circumferential lip extending radially outwardly from the annular body.

15. A battery pack comprising:
a battery housing;
at least one battery cell disposed in the battery housing; and
the explosion-proof venting valve according to claim 1 mounted to the battery housing.
